(19) United States
(12) Patent Application Publication
(10) Pub. No.: US 2026/0063694 A1
(43) Pub. Date: Mar. 5, 2026

(54) METHODS AND APPARATUS FOR COMPONENT/SYSTEM TESTING UNDER MODULATED SIGNALS USING FREQUENCY EXTENDERS

(71) Applicants: Ahmed BEN AYED, Waterloo (CA); Slim BOUMAIZA, Waterloo (CA)

(72) Inventors: Ahmed BEN AYED, Waterloo (CA); Slim BOUMAIZA, Waterloo (CA)

(21) Appl. No.: 19/171,155

(22) Filed: Apr. 4, 2025

Related U.S. Application Data
(60) Provisional application No. 63/688,031, filed on Aug. 28, 2024.

(51) Int. Cl. G01R 27/26; G01R 27/06; G01R 29/10; G01R 31/28

(52) U.S. Cl. CPC G01R 27/26; G01R 27/06; G01R 29/10; G01R 31/2822

(57) ABSTRACT

A measurement system is described for the comprehensive characterization of millimeter-wave/sub-THz devices under both continuous-wave (CW) and modulated signal excitation. CW measurement setups, which include a vector network analyzer (VNA) and VNA frequency extenders (VNA-EXT) are enhanced by the integration of an IF vector signal generator (VSG) and IF vector signal analyzer (VSA). The measurement system incorporates a processing unit configured and operable to process a modulated test signal to mitigate nonlinear behavior. A linearization algorithm is used to linearize the frequency multipliers within the VNA-EXT, ensuring error-free RF modulated signal generation at a device under test (DUT) input reference plane.

This nonprovisional application claims priority to U.S. Provisional Application No. 63/688,031, which was filed on Aug. 28, 2024, and is herein incorporated by reference.

### BACKGROUND OF THE INVENTION

### Field of the Invention

Embodiments of the disclosure relate to methods and apparatus in the field of measurement systems pertaining to the use of frequency extenders, traditionally employed for continuous-wave (CW) testing, in generating modulated signals and performing comprehensive component and system testing at high frequencies.

### Description of the Background Art

The rapid evolution of communication and sensing systems has driven a growing demand for higher data rates and superior signal quality. Central to this advancement are measurement instruments capable of precisely characterizing radio frequency (RF) systems and components under both continuous-wave (CW) and wideband modulated signal excitation conditions.

At frequencies exceeding the ratings of standard equipment precise characterization is typically achieved using two separate setups: (i) a vector network analyzer (VNA) and frequency extenders for CW characterization, and (ii) wideband up-converters and down-converters, along with wideband signal generators and analyzers for modulated signal testing.

A vector network analyzer (VNA) is a specialized electronic test instrument used to measure the electrical network parameters of RF and microwave components. It is primarily used to characterize components such as antennas, filters, and amplifiers by analyzing how they respond to different frequencies. A key function of a VNA is S-parameter measurement which measures scattering parameters (S11, S21, etc.), which describe how RF signals are reflected and transmitted through a device.

A device under test (DUT), such as components of a communications system, can be characterized by applying a repetitive complex-modulated RF signal and analyzing the resulting output RF signal. These measurements enable the evaluation of key DUT parameters, including gain, delay, and distortion. A test instrument, such as a VNA with an integrated superheterodyne receiver is commonly used to conduct these measurements. Typically, the superheterodyne receiver captures an output RF signal, down converts it to a lower frequency intermediate frequency (IF) signal and then digitizes the IF signal using an analog-to-digital converter (ADC). The digitized IF signal is then processed to extract amplitude, phase, and other relevant information for characterizing the DUT.

Frequency extenders are used in RF measurement systems to extend the operating frequency range of test and measurement equipment, such as vector network analyzers (VNAs) signal analyzers and signal generators. They allow these instruments to measure signals at higher frequencies than their native capabilities. In the test and measurement field, there are different types of frequency extenders; they include devices such as multipliers and mixers and a combination of both.

One group of frequency extenders relies on frequency multiplication as a means for generating high-frequency RF signals. In such devices, an output signal frequency is an integer harmonic (multiple) of an input signal frequency. A frequency extender operating based on this principle can extend the frequency of a signal generator or other frequency source by a fixed multiple.

Another group of frequency extenders operates on a principle of heterodyne mixing, in which a local oscillator (LO) signal is mixed with an RF signal to produce an intermediate frequency signal IF_{X} i.e. IF_{X}=RF±LO, which is then used by an analyzer for spectrum and signal analysis.

VNA frequency extenders (VNA-EXT) are designed to work with a VNA to measure a DUT complex S-parameters at frequencies that stretch beyond the standard range of the VNA. For frequency extension, these systems include both types of devices—multipliers and mixers. The multipliers are used for generating high-frequency RF signals and the mixers are used to capture incident and reflected RF waves of the DUT.

An exemplary VNA extension system (FIG. 1) comprises two VNA-EXTs. Each VNA-EXT comprises a multiplier chain for converting an RF signal to the required test frequency range and typically two receivers/down-converters, driven by a LO to produce IF test and IF reference signals. The IF signals are fed into the VNA receivers to measure the S-parameters. While the actual RF test frequency could be in a range of several hundred gigahertz, the down-converted IF signals are in the range of tens of megahertz.

One widely used instrumentation device for signal analysis is a Vector Signal Analyzer (VSA). A VSA measures the magnitude and phase (or in-phase and quadrature components) of an input signal, enabling both time-domain and frequency-domain analysis. It is commonly used to characterize modulated signals, providing key measurements such as error vector magnitude (EVM), adjacent channel power ratio (ACPR) and spectral flatness. A VSA generally comprises a down-conversion and digitization stage, a digital signal processor (DSP), and a display or data output system. An input signal is down-converted using a local oscillator (LO) and a mixer, where the LO frequency is generated by a phase-locked loop (PLL) or synthesizer, often incorporating a direct digital synthesis (DDS) source for precise tuning. The down-converted signal is then digitized using an ADC, where the sampling rate may be adjusted dynamically based on the frequency span under consideration, or a fixed sampling rate may be used with decimation or resampling to match the required analysis bandwidth. Depending on the implementation, filtering may be applied at the RF, IF, or baseband stage to define the analysis bandwidth, suppress out-of-band noise, and mitigate aliasing effects, though some architectures may forgo filtering altogether.

Vector signal generation refers to the process of creating complex modulated signals with both amplitude and phase variations, commonly used communication and RF testing applications. Unlike traditional single-tone signal generators, a vector signal generator (VSG) produces digitally modulated signals that simulate real-world transmission conditions. An arbitrary waveform generator (AWG) allows custom waveform design to replicate real-world signals and impairments, capable of generating user-defined waveforms with precise control over amplitude, phase, and frequency. For example, the AWG generates baseband I/Q waveforms, which are then upconverted by the VSG to an IF/RF frequency for testing a DUT.

In RF communications, continuous wave (CW) refers to an unmodulated RF signal with a constant amplitude and frequency. CW signals are commonly used in RF component testing to evaluate devices such as power amplifiers, filters, etc. by providing a stable test signal. CW signals are also used as local oscillators in RF mixers for frequency conversion.

Although effective and widely adopted, the use of separate setups for CW and modulated signal testing presents several challenges due to differences in signal characteristics, test equipment, and system requirements. Modulated signal testing introduces nonlinear effects such as intermodulation, compression, and adjacent channel interference. In order to generate high-frequency CW or modulated signals, frequency multipliers (FX) are commonly adopted. However, the intrinsic nonlinear distortions exhibited by FXs have predominantly constrained the utilization of this architecture to applications involving spectrally inefficient and constant-envelope signals. Added challenges include increased measurement complexity, higher costs, increased test time and potential inaccuracies or repeatability issues, particularly during on-wafer measurements where repeated probing and un-probing are necessary when switching between setups. Furthermore, the current separate setup approach is inadequate for conducting modulated signal S-parameters measurements and load pull measurements under modulated signal excitation.

### SUMMARY OF THE INVENTION

Various embodiments of a measurement system for characterizing high-frequency RF components under continuous-wave (CW) and modulated signal testing are described herein.

In accordance with the present invention, in one set of embodiments, a measurement system is described for the comprehensive characterization of millimeter-wave/sub-THz devices under both CW and modulated signal excitation. Traditional CW measurement setups, which include VNAs and VNA-EXTs, are enhanced by the integration of an IF VSG and IF VSA thereby enabling modulated signal generation and analysis. This approach provides a unified solution for both CW and modulated signal testing.

In accordance with another aspect of the present invention there is provided a measurement system for the generation of an RF modulated signal at the DUT reference plane by feeding the VNA-EXT with an IF modulated signal from a VSG during modulated signal testing, thereby eliminating the need for a mixer or having to remove the CW measurement setup during the modulated signals testing. The IF VSAs are concurrently connected to the VNA frequency extenders, allowing for the capture of wideband RF modulated signals at the DUT input and output reference planes.

In accordance with a further aspect of the present invention there is provided a measurement system facilitates the generation of RF modulated signals at the DUT reference plane by feeding the VNA-EXT with an IF modulated signal from a VSG during modulated signal testing, thereby eliminating the need for a mixer. The DUT output is connected to an RF Incident and Reflected Wave Analyzer for calibration and optionally connected concurrently to an RF VSA, allowing for the capture of wideband RF modulated signals at the DUT output reference plane. The RF Incident and Reflected Wave Analyzer, comprising a coupler and mixers, is used to sample the incident and reflected waves at the DUT output signal for CW testing and/or calibration. The RF VSA is optionally coupled to the DUT output when modulated signal analysis is required.

In accordance with a further aspect of the present invention there is provided a measurement system including a processing unit configured and operable to process a modulated test signal to mitigate nonlinear behavior. A linearization algorithm is used to linearize the frequency multipliers within the VNA-EXT, ensuring error-free RF modulated signal generation at the DUT input reference plane.

In accordance with a further aspect of the present invention there is provided a measurement system to enable modulated signal S-parameter measurements, offering precise characterization under modulated conditions. The system is also suitable for active and passive load pull measurements with modulated signals, expanding its applicability in advanced testing scenarios.

In accordance with a further aspect of the present invention there is provided a measurement system for the generation of an RF modulated signal at the DUT reference plane by feeding the VNA-EXT from the IF VSG during modulated signal testing. The VNA-EXT is used as a frequency multiplier as a means for generating high-frequency RF signals.

Unless otherwise specified, when an element or component is described as being “connected to” or “coupled to” another element or component, it is understood that the connection can be either direct or indirect, with one or more intervening elements or components present. These terms broadly encompass scenarios where intermediate elements or components facilitate the connection between the two.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a typical VNA extension system.

FIG. 2 illustrates a first embodiment of the present disclosure.

FIG. 3 illustrates a second embodiment of the present disclosure.

FIG. 4 illustrates an IF Vector Signal Generator (VSG).

FIG. 4a illustrates a third embodiment of the present disclosure.

FIG. 5 illustrates an ideal gain block.

FIG. 6 illustrates an ideal VNA Frequency Extender (VNA-EXT).

FIG. 7 illustrates a measurement setup.

FIG. 8 illustrates measured PSD and constellation, 256-QAM 400 MHz OFDM.

FIG. 9 illustrates measured gain and phase distortion, 256-QAM 400 MHz OFDM.

FIG. 10 illustrates measured PSD and constellation, 256-QAM 800 MHz OFDM.

FIG. 11 illustrates measured gain and phase distortion, 256-QAM 400 MHz OFDM.

FIG. 12 illustrates a measurement setup.

### DETAILED DESCRIPTION

While the invention is receptive to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

A measurement system is described capable of precisely characterizing RF components under continuous-wave (CW) and wideband modulated signal testing conditions. At millimeter-wave frequencies, this precise characterization uses VNA frequency extenders to enable CW characterization and using wideband up-converters and down-converters for the modulated signal testing.

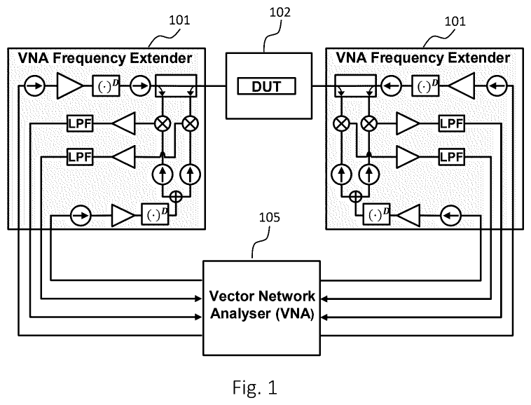

To generate high-frequency RF CW or modulated signals, frequency multipliers (FX) are used. For a VNA-EXT, FXs are used in the main signal path used to excite the device-under-test (DUT), as depicted in FIG. 1. Similarly, for the modulated signals, a local oscillator (LO) path exciting the up and down converter mixers typically incorporate FXs. FX-based upconverters are used for generating vector-modulated signals at millimeter wave frequencies where the FX is placed in the main signal path. FX based up-converters offer notable advantages, including the capability to generate signals that can exceed a transistor's fmax. Moreover, using FXs for signal up-conversion alleviates the need for a high-frequency LO signal which may be subject to deteriorated phase noise performance; instead, the RF signal is directly generated from the input IF signal.

The use of digital predistortion (DPD) in mitigating distortions caused by high-efficiency power amplifiers (PAs) has been well established. However, when applied to linearizing frequency modulators, DPD performance degrades as signal bandwidth increases. Additionally, the effectiveness of linearization is often constrained by the selection of DPD basis functions, leading to suboptimal results. To achieve optimal linearization in nonlinear PAs, iterative learning control (ILC) is used in instrumentation such as VNAs for source signal conditioning. ILC enables the identification of an optimal predistorted signal without being limited by estimation inaccuracies.

A system is herein described for testing components and systems under modulated signals using frequency extenders. A unified measurement system is disclosed to facilitate the comprehensive characterization of DUTs under CW and modulated signal excitations. The system leverages VNA-EXTs to enable RF-modulated signal generation and analysis. An ILC linearization method, specifically designed for FXs, is used to linearize the FX within the VNA-EXT, thus enabling generation of wideband modulated signals at RF frequencies with exceptional signal integrity.

FIG. 1 illustrates an exemplary VNA extension system configured according to embodiments of the present invention. The system comprises a VNA 105 and VNA frequency extenders 101 coupled to a DUT 102 used for continuous-wave (CW) signal measurements. The VNA frequency extenders 101 are designed to work with the VNA 105 to measure complex scattering parameters (S-parameters) of the DUT 102 at frequencies that stretch beyond the standard range of the analyzer. The DUT 102 may be any type of electronic device such as an amplifier, a mixer or a converter, for example that provides an output RF signal in response to a RF signal input by the RF signal source i.e. the VNA frequency extenders 101 coupled to the DUT 102.

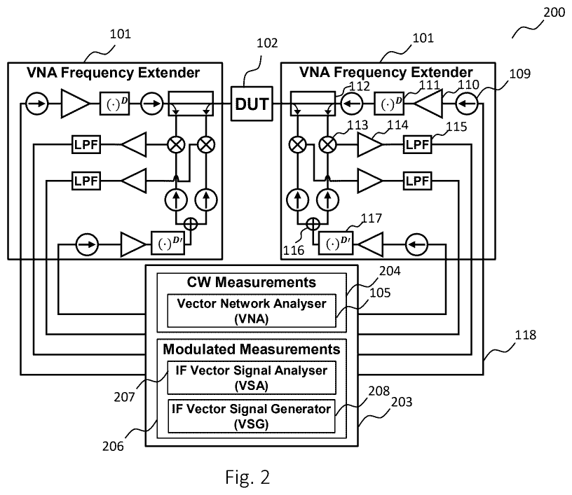

FIG. 2 illustrates a first embodiment of the present disclosure, depicting a measurement system 200 using VNA frequency extenders 101 for both continuous-wave (CW) signal measurements 204 and modulated signal measurements 206. The measurement system 200 uses VNA frequency extenders 101 for signal generation and analysis, extending the operational frequency range of the measurement system equipment 203. The RF ports of the VNA frequency extenders 101 are coupled to the inputs and outputs of the DUT 102. The VNA frequency extender 101 comprises a coupler 112, isolators 109, frequency multipliers 111 and 117, mixers 113, driver amplifiers 110, low-noise amplifiers (LNA) 114 and low-pass-filters (LPF) 115. The IF input and output ports of the VNA frequency extenders 101 are coupled with the measurement system equipment 203 via a plurality of cables 118. Measurement system equipment 203 comprises a VNA 105, IF vector signal generators (VSG) 208 and IF vector signal analyzer (VSA) 207. The VNA is used for CW signal measurements 204. The VSG 108 and the VSA 107 are used for used for modulated signal testing 206.

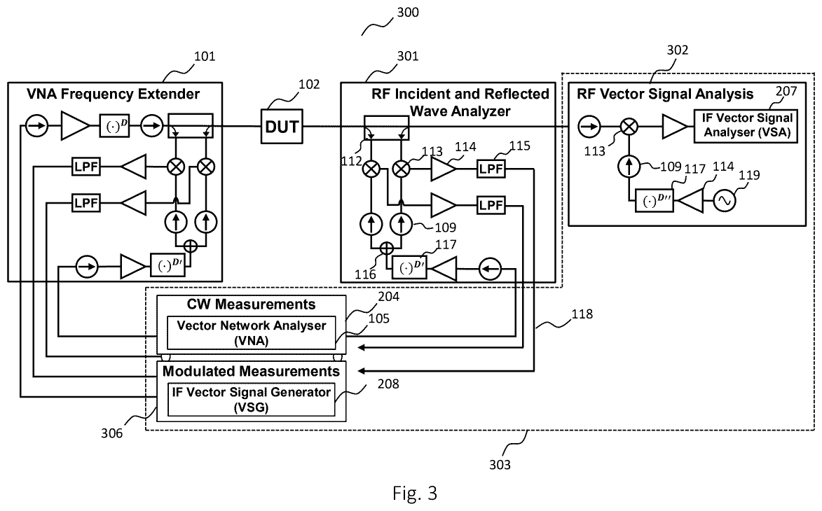

FIG. 3 illustrates a second embodiment of the present disclosure, depicting a measurement system 300 for continuous-wave (CW) signal measurements 204 and modulated signal measurements 306. The measurement system 300 uses a VNA frequency extender 101 for signal generation and utilizes an RF Incident and Reflected Wave Analyzer 301 and RF vector signal analyzer 302 to measure the DUT 102 output. The RF output port of the VNA frequency extender 101 is coupled to the input of DUT 102. The DUT 102 output is coupled to the RF Incident and Reflected Wave Analyzer 301. The RF output port of the RF Incident and Reflected Wave Analyzer 301 is connected to the input port of the RF VSA 302 for down-conversion and signal analysis.

The RF Incident and Reflected Wave Analyzer 301 comprises a coupler 112, isolators 109, a frequency multiplier 117, mixers 113, low-noise amplifiers 114, and low-pass-filters 115. The IF input/output ports of the RF Incident and Reflected Wave Analyzer 301 are coupled with the measurement system equipment 303 via a plurality of cables 118.

The RF vector signal analyzer 302 comprises a down-conversion stage and an IF VSA 207. The down-conversion stage comprises a mixer 113, isolators (109), a frequency multiplier 117, low-noise amplifiers 114, and local oscillator 119.

The measurement system equipment 303 includes a VNA 105 for CW signal measurements 204, and IF VSG 208 and RF VSA 302 for modulated signal measurements 306.

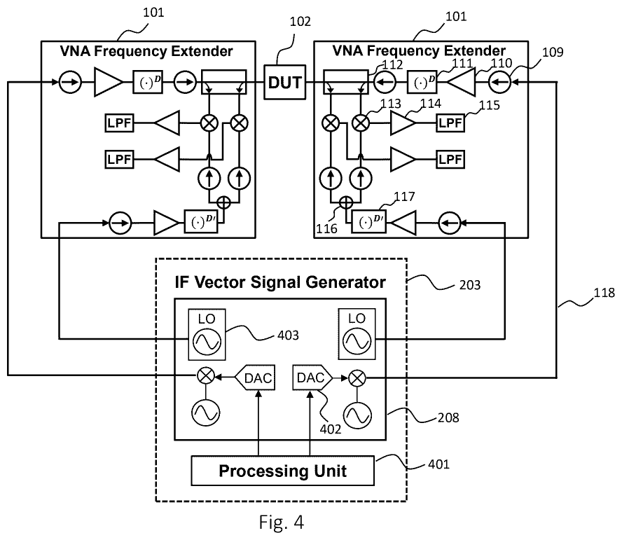

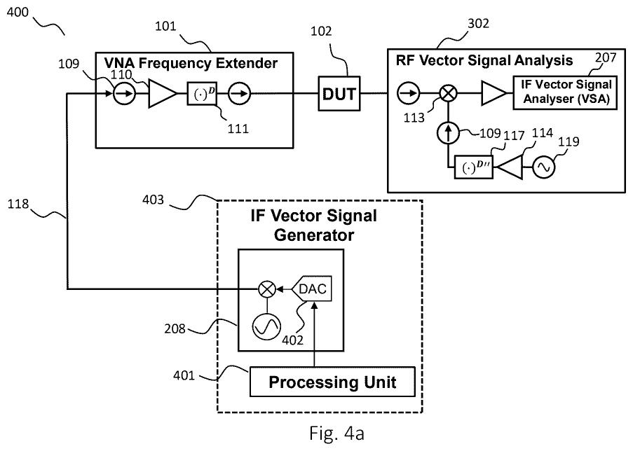

FIG. 4 illustrates an IF vector signal generator 208 for generating the IF modulated signal input to the VNA frequency extenders 101 and LOs 403 to produce IF test and IF reference signals. A processing unit 401 is used to drive the baseband digital-to-analog converters (DAC) 402 to generate a desired RF test signal. The RF test signal is further modulated to produce the IF modulated signal.

FIG. 4a illustrates a third embodiment of the present disclosure, depicting a measurement system 400 for generating high-frequency RF modulated signals. Measurement system 400 comprises an IF vector signal generators (VSG) 208 and VNA frequency extender 101 used to excite a device-under-test (DUT). The VNA frequency extender 101 relies on frequency multiplication as a means for generating high-frequency signals comprising a frequency multiplier 111 operable in the signal path for generating high-frequency RF modulated signals to excite the device-under-test (DUT), as depicted in FIG. 4a. A processing unit 401 is used to drive the baseband digital-to-analog converters (DAC) 402 to generate a desired RF test signal. The RF test signal is further modulated to produce the IF modulated signal. The RF vector signal analyzer 302 comprises a down-conversion stage and an IF VSA 207. The down-conversion stage comprises a mixer 113, isolators 109, a frequency multiplier 117, low-noise amplifiers 114, and local oscillator 119.

In an embodiment, the processing unit 401 comprises a central processing unit (CPU), for example, executing an algorithm. The processing unit 401 may include a storage device, such as a random access memory (RAM), read-only memory (ROM), electrically programmable ROM (EPROM), solid-state drive (SSD), or the like. Data from various measurements may be stored in the storage device and displayed for analysis on a display system such as a flat panel display (FPD).

Processing unit 401 may also comprise an FPGA configured and operable to drive the baseband DAC 402 to generate a desired RF test signal.

Processing unit 401 and other components of measurement system 200 and measurement systems 300 enabling transmission of communication and data and control signals, may be incorporated without departing from the scope of the present teachings.

Because FIGS. 4 and 4a are simplified block diagrams, various embodiments may include additional components, e.g. stages, and may be configured slightly differently, while still including the features further described below, and which FIGS. 4 and 4a are intended to convey in the context of the embodiment of the IF VSG 203.

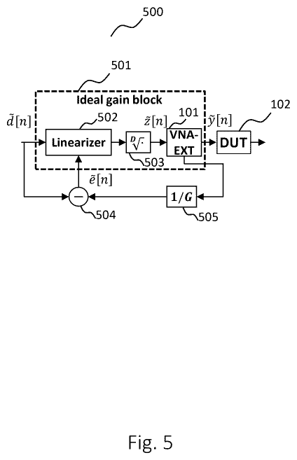

In an embodiment, the measurement systems illustrated in FIGS. 2, 3, 4 and 4a respectively incorporate a processing unit 401 configured and operable to process a modulated test signal to mitigate nonlinear behavior therein produce an ideal gain block 500 illustrated in FIG. 5. The processing unit 401 executes a first linearization algorithm formulated to linearize the frequency multipliers within the VNA frequency extenders to ensure error-free RF modulated signal generation at the DUT input reference plane. FIG. 5 illustrates the first linearizer 502 followed by a Dth root function 503 in baseband. The output of the Dth root function is then converted to continuous time using the DAC 402, which feeds the VNA frequency extender VNA frequency extender 101. The cascade of the linearizer 502, the Dth root function 503, and the VNA frequency extender 101 constitutes an ideal gain block that performs frequency translation from the IF frequency at the VNA frequency extender input to the RF frequency at the VNA frequency extender output, subsequently connecting to the DUT 102. The objective of the linearization is to minimize the error 504 between the VNA frequency extender 101 output, normalized by the VNA frequency extender gain 505, and the linearizer input signal.

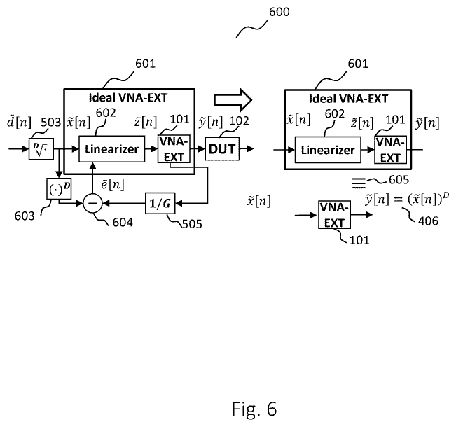

In a further embodiment, the measurement systems illustrated in FIGS. 2, 3, 4 and 4a respectively incorporate a processing unit 401 configured and operable to process a modulated test signal to mitigate nonlinear behavior therein to produce an ideal VNA frequency extender 600 illustrated in FIG. 6. A second linearization algorithm is used to linearize the frequency multipliers within the VNA frequency extenders to ensure error-free RF modulated signal generation at the DUT input reference plane. FIG. 6 illustrates a second linearizer 602, which is preceded by a Dth root function 503 in baseband. The second linearizer 602 output is then converted to continuous time using the DAC 402, which feeds the VNA frequency extender 101. The cascade of the second linearizer 602 and the VNA frequency extender 101 constitutes an ideal VNA frequency extender that performs an ideal power function 605, translating the IF frequency at the VNA frequency extender input to the RF frequency at the VNA frequency extender output, subsequently connecting to the DUT 102. The objective of the linearization is to minimize the error 604 between the VNA frequency extender 101 output, normalized by the VNA frequency extender gain 505, and the linearizer input signal processed through an ideal power of D function 603.

In a further embodiment, the measurement systems illustrated in FIGS. 2, 3, 4 and 4a respectively incorporate a processing unit 401 configured and operable to process a modulated test signal to mitigate nonlinear behavior, utilizing the first or second linearizers to perform modulated signal testing. This testing comprising distortion measurement using two-tone excitation as well as communication/sensing signals such as single carrier and orthogonal frequency-division multiplexing (OFDM) signals. The modulated signal testing is used to measure normalized mean square error (NMSE), error vector magnitude (EVM), adjacent channel power ratio (ACPR), or other metrics used for characterizing components and systems. Furthermore, the modulated signal testing comprises scattering-parameter (S-parameters) measurements under wideband modulated signal excitation, referred to as modulated signal S-parameters.

In a first configuration, the linearization of the frequency multipliers within the frequency extenders uses the first linearization method. The algorithms used to linearize the within VNA frequency extenders in the embodiments illustrated in FIG. 5 and FIG. 6, respectively, are presented as follows. With respect to the following description, \tilde{d}[n], \tilde{z}[n], and \tilde{y}[n] denote the desired VNA-EXT output, the VNA-EXT input and the measured VNA-EXT output, respectively.

Using an additive error model, the frequency multiplier output \tilde{y}[n] is expressed as:

$$\tilde{y} [ n ] = {G ( \tilde{z} [ n ] )}^{D} + \tilde{e} ( \tilde{z} ( n ) ) . \qquad ( 1 )$$

Here, G denotes the FX's conversion gain, D is multiplication factor, \tilde{e}(\tilde{z}(n)) represents the VNA-EXT's nonlinearity, \tilde{z}(n)=(\tilde{z}[n], . . . , \tilde{z}[n−M])^{T}, and M is the system's memory depth.

To linearize the VNA-EXT output, an extension of the iterative-learning control (ILC) solution commonly applied to PAs is used. Accordingly, if the linearizer effectively compensates for the FX nonlinearity, \tilde{y}[n] in (1) simplifies to the desired input signal \tilde{d}[n] scaled by the VNA-EXT conversion gain. Assuming the existence of such a solution, \tilde{z}[n] in (1) can be expressed as a function of the desired and error signals as follows:

$$\tilde{z} [ n ] = \sqrt[D]{\frac{\tilde{d} [ n ] - \tilde{e} ( \tilde{z} ( n ) )}{G}} \qquad ( 2 )$$

Considering a weakly nonlinear scenario, (2) can be solved iteratively to yield a sequence of predistorted signals, \tilde{z}ₖ[n] for k=1, 2, . . . , as follows:

$${\tilde{z}}_{k + 1} [ n ] = \sqrt[D]{\tilde{d} [ n ] - \frac{\tilde{e} ( {\tilde{z}}_{k} ( n ) )}{G}} \qquad ( 3 )$$

where the initial condition is set as \tilde{z}₁[n]=

$${\tilde{z}}_{1} [ n ] {=}^{D} \sqrt{\tilde{d} [ n ]} .$$

If \tilde{y}ₖ[n] is taken to be G(\tilde{z}ₖ[n])^{D}+\tilde{e}ₖ(\tilde{z}ₖ(n)), (3) simplifies to:

$${\tilde{z}}_{k + 1} [ n ] = \sqrt[D]{{( {\tilde{z}}_{k} [ n ] )}^{D} - μ \frac{{\tilde{y}}_{k} [ n ] - G \tilde{d} [ n ]}{G}} \qquad ( 4 )$$

where μ∈(0,1] is a learning parameter introduced to help with convergence. Therefore, (4) encapsulates the iterative training process of the PA-based ILC linearizer.

In a second configuration the linearization of the frequency multipliers within the frequency extenders uses the second linearization method to linearize the FXs within VNA frequency extenders shown in FIG. 4. The optimal linearization signal can be expressed using an additive model such that:

$$\tilde{z} [ n ] = \sqrt[D]{\tilde{d} [ n ]} + {\tilde{e}}^{′} [ n ] . \qquad ( 5 )$$

Where \tilde{e}′[n] is a high-order nonlinearity term assumed to be much smaller than

$$\sqrt[D]{\tilde{d} [ n ]} .$$

Substituting, (5) in (1), we have:

$$\tilde{y} [ n ] = {G ( \sqrt[D]{\tilde{d} [ n ]} + {\tilde{e}}^{′} [ n ] )}^{D} + \tilde{e} ( \tilde{z} ( n ) ) \qquad ( 6 )$$

Using binomial approximation, (6) can be simplified to:

$$\tilde{y} [ n ] \approx GD \tilde{z} [ n ] {( \sqrt[D]{\tilde{d} [ n ]} )}^{D - 1} - G ( D - 1 ) \tilde{d} [ n ] + \tilde{e} ( \tilde{z} ( n ) ) \qquad ( 7 )$$

Furthermore, if \tilde{z}[n] is taken to be the optimal linearizer solution, \tilde{y}[n] in (7) simplifies to the desired input signal \tilde{d}[n] scaled by the VNA-EXT conversion gain. Consequently, \tilde{z}[n] in (7), can be expressed as follows:

$$\tilde{z} [ n ] = \sqrt[D]{\tilde{d} [ n ]} - \frac{\tilde{e} ( \tilde{z} ( n ) )}{{GD ( \sqrt[D]{\tilde{d} [ n ]} )}^{D - 1}} \qquad ( 8 )$$

Considering a weakly nonlinear scenario, the recursive function (8) can be solved iteratively as follows:

$${\tilde{z}}_{k + 1} [ n ] = \sqrt[D]{\tilde{d} [ n ]} - \frac{\tilde{e} ( {\tilde{z}}_{k} ( n ) )}{{GD ( \sqrt[D]{\tilde{d} [ n ]} )}^{D - 1}} \qquad ( 9 )$$

where the initial condition is set as \tilde{z}₁[n]=

$${\tilde{z}}_{1} [ n ] {=}^{D} \sqrt{\tilde{d} [ n ]} .$$

If \tilde{y}[n] is taken to be the FX output at the kth iteration, from (7), (9) can be rewritten as follows:

$${\tilde{z}}_{k + 1} [ n ] = {\tilde{z}}_{k} [ n ] - μ \frac{{\tilde{y}}_{k} [ n ] - G \tilde{d} [ n ]}{{GD ( \sqrt[D]{\tilde{d} [ n ]} )}^{D - 1}} \qquad ( 10 )$$

where μ∈(0,1] is a learning parameter introduced to help with convergence. Therefore, (10) encapsulates the iterative training process of the proposed FX-based ILC linearizer. Note, for PAs (D=1), both (4) and (10) simplify to the same solution. This demonstrates continuity in the solution between the proposed ILC algorithm and those previously established in the literature for PAS.

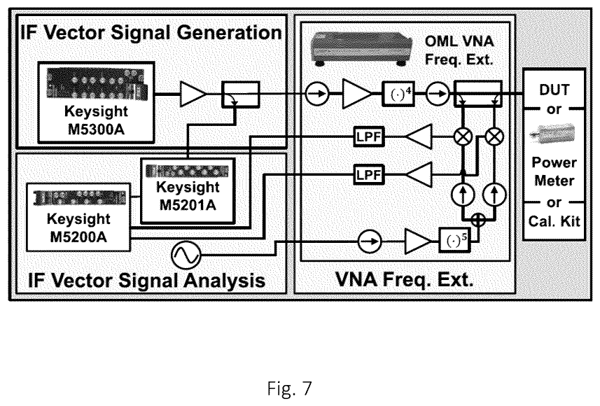

FIG. 7 illustrates a measurement system using the ILC algorithm to linearize the FX within VNA frequency extenders. In FIG. 7, The FX to be linearized is a quadrupler (D=4) within an Oleson Microwave Labs (OML) V-band VNA frequency extender. The modulated test signals used in the experiment were generated using two 14-bit, 2 GHz bandwidth, 2.4 Gsps RF-AWGs (M5300A from Keysight) with their outputs frequency-stitched to generate up to 4 GHz of modulated bandwidth centered around an intermediate frequency (IF) of 14.4 GHz. A driver amplifier was then used to amplify the RF-AWG IF signal output before being fed to the OML IF input port through a directional coupler. The coupler-coupled port was used for transmitter calibration. The output of the OML's frequency quadrupled centered at 57.6 GHz was then sampled and downconverted using the OML's built-in directional coupler and downconverter mixer and was then captured using a 12-bits, 2 GHz bandwidth and 4.8 Gsps digitizer (M5200A from Keysight). To accommodate for the OML's feedback path limited modulation bandwidth of 300 MHz, a frequency stitching receiver-based approach was adopted where the OML's mixer LO signal was swept, and the wideband spectrum at the FX output was captured sequentially and reconstructed digitally. The OML's waveguide output was connected to a power meter for power calibration.

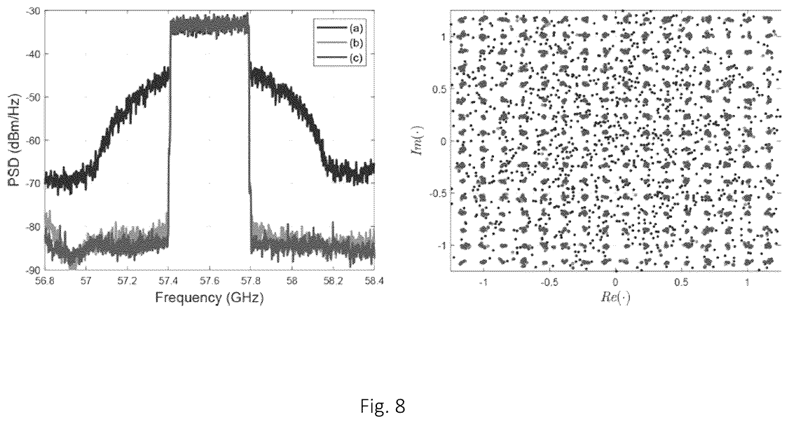

FIG. 8 depicts the measurement results illustrating the power spectral density (PSD) (left) and constellation (right) at the OML's frequency quadrupler output when driven with a 256-QAM 400 MHz OFDM signal. FIG. 8 illustrates; (a) before linearization with Dth-root applied, (b) with PA-based ILC applied, and (c) with proposed FX-based applied.

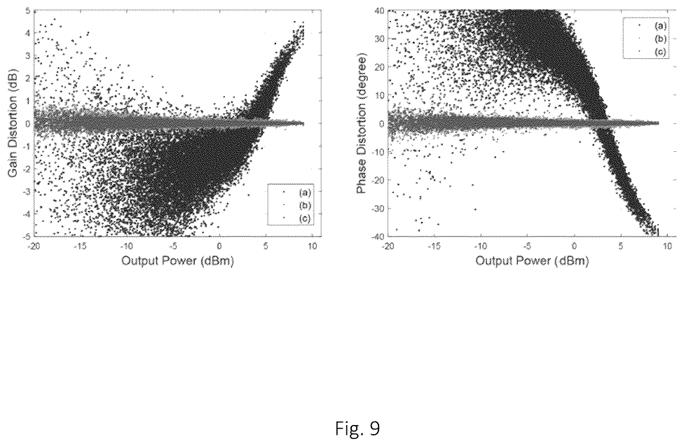

Using the ILC algorithms, the EVM and ACPR improved from 44.8% and −17.1/−17.0 dBc, before linearization and with Dth-root applied in (a), to 1.6% and −49.2/−49.3 dBc in (b) using the PA-based ILC, and to 1.45% and −50.7/−51.0 dBc in (c) using the described FX-based ILC. Both ILC algorithms were able to achieve excellent linearization performance at the quadrupler output as illustrated by the flat gain (left) and phase (right) distortion plots shown in FIGS. 9-11.

FIG. 9 illustrates; (left) measured gain distortion and (right) phase distortion at OML's frequency quadrupled output when driven with 256-QAM 400 MHz OFDM signal (a) before linearization with Dth-root applied, (b) with linearization method 1 applied, and (c) with linearization method 2 applied.

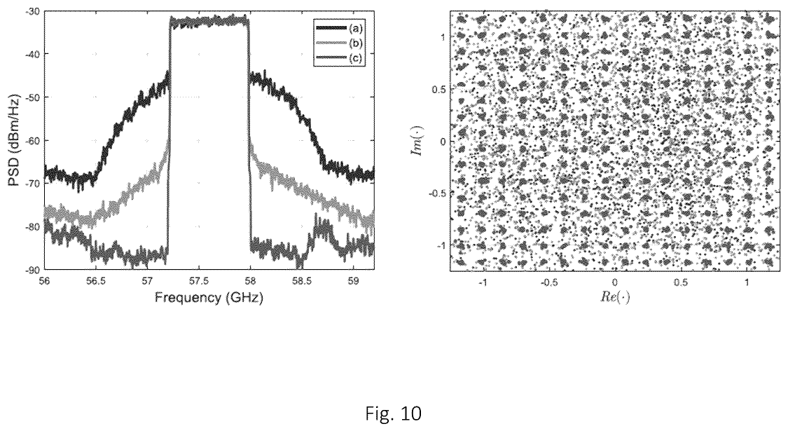

FIG. 10 provides measurement results illustrating the PSD (left) and constellation (right) at the OML's frequency quadrupler output when driven with a 256-QAM 800 MHz OFDM signal. FIG. 10 illustrates; (a) before linearization with Dth-root applied, (b) with linearization method 1 applied, and (c) with linearization method 2 applied.

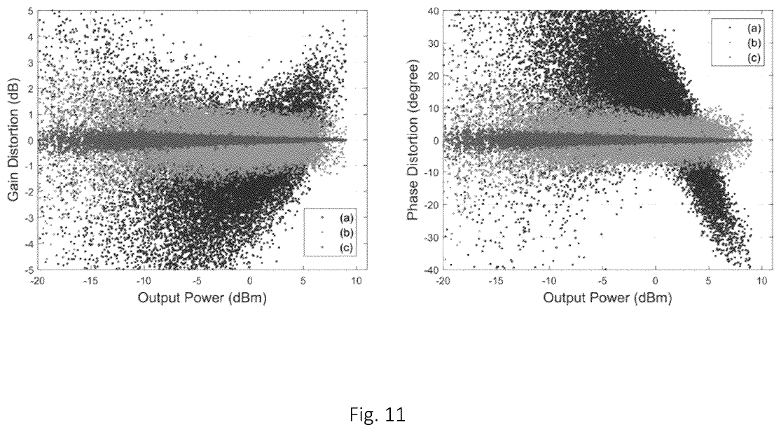

Applying the disclosed ILC algorithms, the EVM and ACPR improved from 49.4% and −17.9/−15.7 dBc, before linearization and with Dth-root applied in (a), to 13.9% and −36.2/−34.8 dBc in (b) using linearization method 1, and to 1.17% and −51.6/−48.7 dBc in (c) using the disclosed linearization method 2. Note, the deterioration in linearization results by the linearization method 1, compared to method 2, is attributed to linear memory at the OML's frequency quadrupler input, leading to strong nonlinear memory at the FX output. This phenomenon is evident in the gain (left) and phase distortion (right) plots before linearization and with Dth-root applied, as shown in FIG. 11(a), exhibiting pronounced dispersion.

FIG. 11 further illustrates; (left) measured gain distortion and (right) phase distortion at OML's frequency quadrupled output when driven with 256-QAM 800 MHz OFDM signal (a) before linearization with Dth-root applied, (b) with linearization method 1 applied, and (c) with linearization method 2 applied. This strong nonlinear memory adversely impacted the accuracy of the weak nonlinear assumption, causing the linearization algorithm of method 1 to exhibit nonconvergence, as evidenced by the PSD in FIG. 10(b) and the gain (left) and phase (right) distortion plots in FIG. 11(b). In contrast, the disclosed linearization algorithm of method 2 remained unaffected, demonstrating successful convergence and excellent linearization results, as indicated by the flat gain (left) and phase (right) distortion plots in FIG. 11(c).

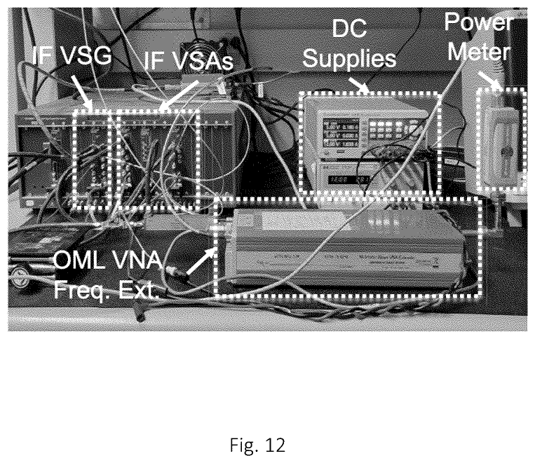

A picture of the measurement setup is shown in FIG. 12.

The teachings contained in the embodiments described herein may be applied to component and system testing under modulated signals using frequency extenders. The foregoing description, for the purpose of explanation, has been described with reference to specific embodiments. However, the illustrative discussions above are not intended to be exhaustive or to limit the application to the precise forms disclosed. Many modifications and variations are possible in view of the above teachings. The embodiments were chosen and described to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the application is not to be limited to the details given herein but may be modified within the scope and equivalents of the appended claims.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A measurement system for testing RF components and systems, the measurement system comprising:
one or more IF vector signal analyzers;
one or more IF vector signal generators; and
one or more VNA frequency extenders, coupled to said one or more IF vector signal generators and said one or more IF vector signal analyzers,
wherein said measurement system is configured and selectively operable for continuous-wave (CW) excitation and modulated signal excitation, using a single measurement set up.

2. The system of claim 1 further comprising one or more processing units configured to generate one or more signals coupled to the inputs of said one or more VNA frequency extenders using a linearization algorithm.

3. The system of claim 1 further comprising one or more processing units configured to generate one or more signals coupled to the inputs of said one or more VNA frequency extenders, the processing including iterative learning control (ILC) to linearize one or more frequency multipliers within said one or more VNA frequency extenders.

4. A measurement system for testing (RF) components and systems, the measurement system comprising:
one or more vector network analyzers;
one or more IF vector signal analyzers;
one or more IF vector signal generators; and
one or more VNA frequency extenders coupled to said one or more vector network analyzers, said one or more IF vector signal generators and said one or more IF vector signal analyzers,
wherein said measurement system is configured and selectively operable for continuous-wave (CW) excitation and modulated signal excitation, using a single measurement set up.

5. The system of claim 4 further comprising one or more processing units configured to generate one or more signals coupled to the inputs of said one or more VNA frequency extenders using a linearization algorithm.

6. The system of claim 4 further comprising one or more processing units configured to generate one or more signals coupled to the inputs of said one or more VNA frequency extenders, the processing including iterative learning control (ILC) to linearize one or more frequency multipliers within said one or more VNA frequency extenders.

7. A measurement system for testing radio frequency (RF) components and systems comprising:
one or more devices under test;
one or more vector network analyzers;
one or more IF vector signal generators;
one or more RF Incident and Reflected Wave Analyzers; and
one or more frequency extenders coupled to said one or more IF vector signal analyzers, said one or more IF vector signal generators and said one or more RF Incident and Reflected Wave Analyzers,
wherein said one or more IF vector signal analyzers and said one or more RF Incident and Reflected Wave Analyzers are coupled to the one or more devices under test and said measurement system is configured and selectively operable for continuous-wave (CW) excitation and modulated signal excitation, using a single measurement set up.

8. The system of claim 7 further comprising one or more processing units configured to generate one or more signals coupled to the inputs of said one or more VNA frequency extenders using a linearization algorithm.

9. The system of claim 7 further comprising one or more processing units configured to generate one or more signals coupled to the inputs of said one or more VNA frequency extenders, the processing including iterative learning control (ILC) to linearize one or more frequency multipliers within said one or more VNA frequency extenders.

10. A method for testing RF components and systems comprising:
generating one or more continuous-wave (CW) signals using one or more VNA frequency extenders;
generating one or more intermediate frequency (IF) signals by frequency mixing one or more input signals with one or more local oscillator signals using one or more IF vector signal generators;
generating one or more modulated output signals by frequency multiplying said one or more intermediate frequency (IF) signals using said one or more VNA frequency extenders;
exciting one or more DUT inputs and outputs with said one or more modulated output signals;
measuring said one or more DUT inputs and outputs;
frequency mixing said one or more modulated output signals to produce one or more reference signals; and
analyzing said modulated output signal, said DUT inputs and outputs, and said one or more reference signals using one or more IF vector signal analyzers,
wherein said measurement system is configured and selectively operable for continuous-wave (CW) excitation and modulated signal excitation, using a single measurement set up.

11. The method of claim 10 further comprising one or more processing units configured for generating said one or more input signals coupled to the inputs of said one or more VNA frequency extenders using a linearization algorithm, wherein said linearization algorithm eliminates non-linearities of said one or more VNA frequency extenders.

12. The method of claim 10 further comprising one or more processing units configured to generate one or more signals coupled to the inputs of said one or more VNA frequency extenders, the processing including iterative learning control (ILC) to linearize one or more frequency multipliers within said one or more VNA frequency extenders.

13. The method of claim 10 further comprising one or more VNAs for analyzing modulated signal scattering parameter measurements and active and passive load pull measurements.

14. The method of claim 10 further comprising coupling one or more RF Incident and Reflected Wave Analyzers to the one or more DUT outputs.

15. A measurement system for testing RF components and systems comprising:
one or more IF vector signal generators; said one or more IF vector signal generators configured and operable to generate one or more IF modulated signals;
one or more VNA frequency extenders, coupled to said one or more IF vector signal generators;
one or more frequency multipliers in a main signal path configured and operable for frequency multiplication;
one or more devices under test (DUT) coupled to said one or more VNA frequency extenders;
one or more RF vector signal analyzers coupled to said devices under test (DUT); and
one or more processing units coupled to the inputs of said one or more VNA frequency extenders, said one or more processing units configured and operable to generate one or more modulated test signals using a linearization algorithm.

16. The system of claim 15 further comprising one or more processing units configured and operable to generate said one or more modulated test signals using iterative learning control (ILC) to linearize said one or more frequency multipliers.

17. A method for testing RF components and systems comprising:
processing one or more modulated test signals using a linearization algorithm;
generating one or more intermediate frequency (IF) modulated signals by frequency mixing one or more RF test signals with one or more local oscillator signals using one or more IF vector signal generators;
generating one or more RF modulated signals by frequency multiplying one or more IF modulated signals using one or more frequency multipliers;
exciting one or more devices under test (DUT) with said one or more RF modulated signals;
analyzing said one or more devices under test (DUT) using one or more RF vector signal analyzers.

18. The method of claim 17 further comprising processing said one or more modulated test signals using iterative learning control (ILC) to linearize said one or more frequency multipliers.
